(19) United States
(12) Patent Application Publication
(10) Pub. No.: US 2020/0266607 A1
(43) Pub. Date: Aug. 20, 2020

(54) SINGLE LONGITUDINAL MODE LASER DIODE SYSTEM

(71) Applicant: NECSEL INTELLECTUAL PROPERTY, INC., Pennington, NJ (US)

(72) Inventors: Boris Leonidovich Volodin, Pennington, NJ (US); Vladimir Sinisa Ban, Princeton, NJ (US); Sergei Dolgy, Lambertville, NJ (US)

(73) Assignee: NECSEL INTELLECTUAL PROPERTY, INC., Pennington, NJ (US)

(21) Appl. No.: 16/795,784

(22) Filed: Feb. 20, 2020

Related U.S. Application Data
(63) Continuation of application No. 15/718,633, filed on Sep. 28, 2017.
Application No. 15/718,633 is a continuation of application No. 14/537,725, filed on Nov. 10, 2014, now abandoned.

(51) Int. Cl. H01S 5/065; H01S 5/14; H01S 5/0687

(52) U.S. Cl. CPC H01S 5/0654; H01S 5/141; H01S 5/06837; H01S 2301/163; H01S 5/0687

(57) ABSTRACT

A semiconductor laser diode system may include a single longitudinal mode laser diode and a feedback system that monitors and controls the emission characteristics of the laser diode. The laser diode may include a gain medium and an optical feedback device. The feedback system may include a wavelength discriminator, an optical detector, a microprocessor, and a laser controller. Such a semiconductor laser diode system may be used to produce laser light having coherence length, wavelength precision, and wavelength stability that is equivalent to that of a gas laser. Accordingly, such a semiconductor laser diode system may be used in place of a traditional gas laser.

### CROSS REFERENCE

This application is a continuation of U.S. patent application Ser. No. 15/718,633, filed Sep. 28, 2017, which is a continuation of U.S. patent application Ser. No. 14/537,725, filed Nov. 10, 2014, the disclosure of which is incorporated herein by reference.

### BACKGROUND

Certain applications, such as laser spectroscopy and laser metrology, for example, employ lasers having extremely precise and stable wavelengths, as well as sufficiently long coherence lengths to support the application. Typically, gas lasers are used in such applications because gas lasers are known to have such very precise and stable wavelengths, and sufficiently long coherence lengths.

Gas lasers convert electrical energy to laser light by discharging an electric current through a gas. A common and inexpensive gas laser is the Helium-Neon (HeNe) gas laser. HeNe lasers are available in a variety of colors, such as red (632.8 nm), orange (612 nm), yellow (594 nm), and green (543.5 nm). Other gas lasers, such as argon, krypton, and xenon, as also well known.

In some applications, however, gas lasers may be undesirable. In many applications, semiconductor laser diodes have largely taken the place of traditional gas lasers. However, though laser diodes are often advertised as replacements for gas lasers, it is well known that traditional laser diodes have not been able to replicate the coherence length and wavelength precision and stability of gas lasers.

But laser diodes do have some practical advantages that make them desirable as gas laser replacements. For example, laser diodes are smaller, more efficient, and more versatile than gas lasers. It would be desirable therefore, if there were available a semiconductor laser diode that could replicate the coherence length and wavelength precision and stability of a gas laser.

### SUMMARY

As disclosed herein, a semiconductor laser diode system may include a single longitudinal mode laser diode and a feedback system that monitors and controls the emission characteristics of the laser diode. The feedback system may include a wavelength discriminator, an optical detector, a microprocessor, and a laser controller.

The laser diode may be stabilized according to known laser stabilization techniques. The laser diode may include a gain medium and an optical feedback device. The gain medium may be chosen to most nearly approximate the desired laser emission wavelength. The optical feedback device may feed a narrowband portion of the emitted radiation back into the gain medium to cause the laser diode to achieve single longitudinal mode at the desired wavelength. The optical feedback device may be a volume Bragg grating element, i.e., a three-dimensional optical element having a Bragg grating recorded therein. The volume Bragg grating element may be a bulk of photorefractive glass, having the Bragg grating holographically recorded therein. The Bragg grating may cause a portion of the light emitted from the gain medium to be reflected back into the gain medium as seed light at a very precisely known wavelength.

The wavelength discriminator may receive light emitted from the laser diode. The wavelength discriminator may be a partially reflective optical element that allows most of the light emitted from the laser diode to pass through transparently, and yet diverts a small portion of the light toward the optical detector. The wavelength discriminator may be a second volume Bragg grating element having a Bragg grating recorded therein. The Bragg grating may be formed such that the volume Bragg grating element is basically transparent to the light emitted from the laser diode, and yet diverts a small portion of the light toward the optical detector. The Bragg grating may be formed to be a wavelength-selective Bragg grating. That is, the Bragg grating may be formed such that the portion of the light that is diverted to the optical detector consists of only a certain subset of the wavelengths present in the light emitted from the laser diode. The wavelength discriminator could be an etalon or a diffraction grating.

The optical detector receives the light diverted by the wavelength discriminator. The optical detector detects the optical power distribution over several frequency channels, and produces an electrical signal representative of the optical power distribution. The optical detector may include an arrangement of one or more photodiodes, or it may include one or more charge-coupled devices (CCDs). The optical detector may pass the electrical signal to the microprocessor.

The microprocessor analyzes the electrical signal to assess the emission characteristics of the laser diode. If the microprocessor determines that the emission characteristics of the laser diode are not exactly as they should be, the microprocessor commands the controller to alter a characteristic of the laser diode.

The laser controller may control the temperature, drive current, or cavity length of the laser diode. Based on the commands received from the microprocessor, the laser controller determines whether to alter one, or more, or any, of the laser diode characteristics. The laser controller may issue commands to one or more of a temperature controller, drive current controller, or cavity length controller. The several controllers may all be executed in a single microprocessor, or in different processors.

The temperature controller may cause the temperature of the laser diode to be adjusted by causing a thermoelectric cooler to draw more or less thermal energy from the laser diode. The drive current controller may cause the drive current of the laser diode to be adjusted by causing a current driver to provide more or less drive current to the laser diode. The cavity length controller may cause the cavity length to be adjusted by causing an electromechanical element, such as a piezo element, for example, to increase or decrease the distance between the gain medium and the feedback grating element.

As disclosed herein, such a semiconductor laser diode system may be used to produce laser light having coherence length, wavelength precision, and wavelength stability that is equivalent to that of a gas laser. Accordingly, such a semiconductor laser diode system may be used in place of a traditional gas laser.

### BRIEF DESCRIPTION OF THE DRAWINGS

FIG. 1 is a functional block diagram of an example single longitudinal mode (SLM) laser diode system.

FIG. 2 illustrates how an SLM condition may be achieved in a laser cavity.

FIG. 3 is a plot of laser diode output optical power as a function of drive current, which illustrates an example technique for achieving single longitudinal mode operation of a wavelength-stabilized laser diode.

FIG. 4A is three-dimensional plot of laser diode output optical power as a function of drive current and temperature, and FIG. 4B is three-dimensional plot of laser diode output wavelength as a function of drive current and temperature, which illustrate an example technique for eliminating mode hops during wavelength tuning of an SLM laser diode system.

FIG. 5 provides a functional block diagram of an example laser controller.

FIGS. 6A-6D illustrate the output spectrum (i.e., power vs. wavelength) from, respectively, 6A) a non-stabilized laser diode, 6B) a stabilized non-SLM laser diode, 6C) a stabilized SLM laser diode without active wavelength control, and 6D) a stabilized SLM laser diode with active wavelength control.

FIG. 7 provides comparative data for several different laser types.

FIG. 8 provides a detailed functional block diagram of an example wavelength discriminator using VBG elements.

FIG. 9 provides a detailed functional block diagram of another example wavelength discriminator using a VBG element.

FIG. 10 is a detailed functional block diagram of an example wavelength discriminator using an etalon.

FIG. 11 is a detailed functional block diagram of another example wavelength discriminator using etalons.

### DETAILED DESCRIPTION

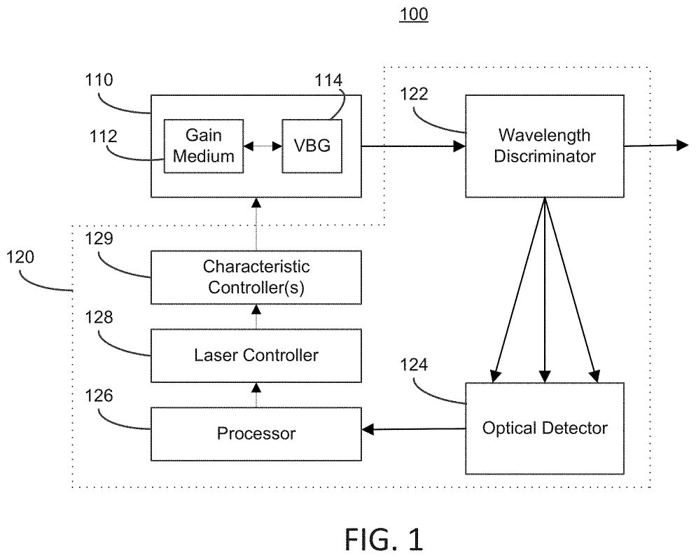

FIG. 1 is a functional block diagram of an example single longitudinal mode laser diode system 100. As disclosed herein, such a semiconductor laser diode system may be used to produce laser light having coherence length, wavelength precision, and wavelength stability that is equivalent to that of a gas laser. Accordingly, such a semiconductor laser diode system may be used in place of a traditional gas laser.

To be used in place of a traditional gas laser, the laser diode system 100 may be configured to achieve a coherence length of at least 30 meters, wavelength precision of ±5 pm, and wavelength stability of less than ±5 pm. It should be understood, of course, that the laser diode system disclosed herein may be used in applications other than in place of traditional gas lasers.

As shown in FIG. 1, the laser diode system 100 may include a single longitudinal mode (SLM) laser diode 110 and a feedback system 120. The feedback system 120 monitors and controls the emission characteristics of the laser diode 110. The feedback system 120 may include a wavelength discriminator 122, an optical detector 124, a processor 126, a laser controller 128, and one or more laser characteristic controllers 129.

The laser diode 110 may include a gain medium 112 and an optical feedback device 114. The gain medium 112 may be chosen to most nearly approximate the desired laser emission wavelength. The optical feedback device 114 may feed a narrowband portion of radiation emitted from the gain medium 112 back into the gain medium 112 to cause the laser diode 110 to achieve single longitudinal mode at a desired wavelength.

The optical feedback device 114 may be a volume Bragg grating element, i.e., a three-dimensional optical element having a Bragg grating recorded therein. The volume Bragg grating element may be a bulk of photorefractive glass, having the Bragg grating holographically recorded therein. The Bragg grating may cause a portion of the radiation emitted from the gain medium 112 to be reflected back into the gain medium 112 as seed light at a very precisely known wavelength.

It should be understood, of course, that the laser diode system disclosed herein may produce laser light having a wavelength that is not equivalent to that of any known gas laser. However, to be used in place of a traditional gas laser, the laser diode system 100 may be configured to produce laser light having a wavelength that is equivalent to that of a known gas laser. For example, the laser diode system 100 may be configured to produce laser light having a wavelength that is equivalent to that of a HeNe gas laser. Specifically, the laser diode system 100 may be configured to produce laser light having a wavelength of 632.8 nm for red, 612.0 nm for orange, 594.0 nm for yellow, or 543.5 nm for green. Argon lasers typically emit at 514.5 nm for green, 457.9 nm for blue, or 488.0 nm for blue-green, among others. Krypton lasers typically emit at 647.1 nm, 413.1 nm, or 530.9 nm, among others.

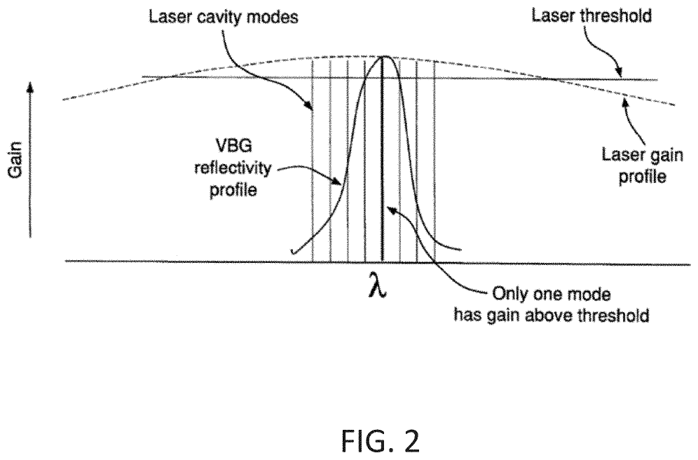

The optical feedback device 114 can be configured to cause the laser diode 110 to achieve single longitudinal mode. As shown in FIG. 2, via a plot of gain vs. wavelength, by comparing the volume Bragg grating (VBG) reflectivity profile against the laser threshold, it can be observed that only one laser cavity mode has gain above the laser threshold. Thus, the optical feedback device 114 can be configured to feed a narrowband portion of radiation emitted from the gain medium back into the gain medium to cause the laser diode to achieve single longitudinal mode. The emission wavelength, or other emission characteristics of the laser diode, may be stabilized using known laser stabilization techniques, such as disclosed and claimed in U.S. Pat. No. 7,298,771, the disclosure of which is incorporated herein by reference.

The wavelength discriminator 122 may receive light emitted from the laser diode 110. The wavelength discriminator 122 may be a partially reflective optical element that allows most of the light emitted from the laser diode 110 to pass through transparently, and yet diverts a small portion of the light toward the optical detector 124. The wavelength discriminator 122 may be a second volume Bragg grating element having a Bragg grating recorded therein. The Bragg grating may be formed such that the volume Bragg grating element is basically transparent to the light emitted from the laser diode 110, and yet diverts a small portion of the light toward the optical detector 124. The Bragg grating may be formed to be a wavelength-selective Bragg grating. That is, the Bragg grating may be formed such that the portion of the light that is diverted to the optical detector 124 consists of only a certain subset of the wavelengths present in the light emitted from the laser diode 110. Other examples of wavelength discriminators include etalons, diffraction gratings, and gas cells, all of which are well known.

The optical detector 124 receives the light diverted by the wavelength discriminator 122. The optical detector 124 detects the optical power distribution over several frequency channels, and produces an electrical signal representative of the optical power distribution. The optical detector 124 may include an arrangement of one or more photodiodes, or it may include one or more charge-coupled devices (CCDs). The optical detector 124 may pass the electrical signal to the processor 126.

The processor 126 may be a microprocessor, for example, that is configured to analyze the electrical signal to assess one or more emission characteristics of the laser diode. If the processor 126 determines that an emission characteristic of the laser diode is undesirable (e.g., the laser diode 110 is emitting laser light having a wavelength or bandwidth that is outside the desired range for performance as an equivalent to a gas laser), the processor 126 may command the laser controller 128 to alter a characteristic of the laser diode 110 to thereby alter the undesired emission characteristic.

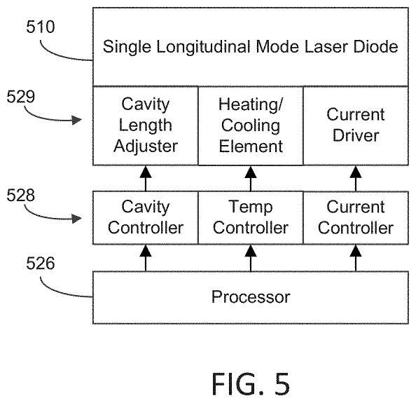

The laser controller 128 may control the temperature, drive current, cavity length, or other characteristic of the laser diode. Based on commands received from the processor 126, the laser controller 128 may determine whether to adjust one, or more, or any, of the laser diode characteristics (e.g., temperature, drive current, and cavity length). The laser controller 128 may issue commands to one or more laser diode characteristic controllers 129. Examples of characteristic controllers are a temperature controller, a drive current controller, and a cavity length controller (see FIG. 5).

The processor 126 and the laser controller 128 may be implemented in single microprocessor, or in different microprocessors. Likewise, the laser diode characteristic controller(s) 129 may be implemented in a single microprocessor, which may be the same microprocessor as the processor 126 and/or laser controller 128, or they may be implemented in different microprocessors.

FIG. 2 provides plots showing how a VBG element can force a laser to operate on a single longitudinal mode. As an example, a VBG element has a narrow wavelength reflectivity, considerably narrower than the width of the gain curve of the active medium of the laser. In order to lase, the individual longitudinal modes of the laser resonator have to exceed the lasing threshold. Due to the highly selective reflectivity of a VBG output coupler, however, only one longitudinal mode of the laser cavity has a gain exceeding the lasing threshold.

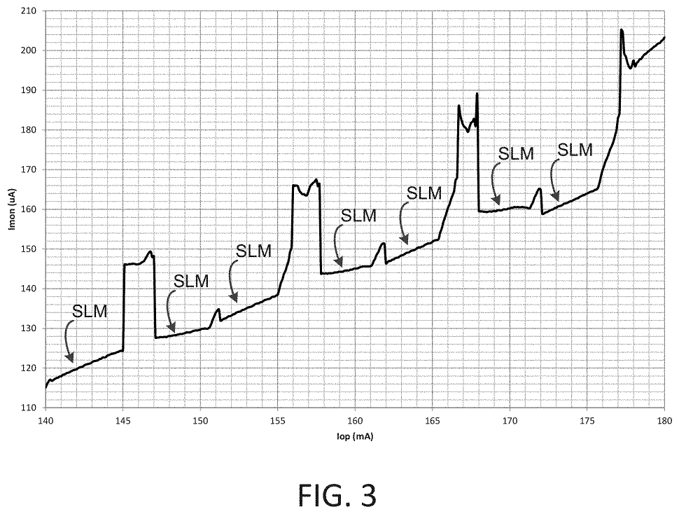

FIG. 3 is a plot of laser output power vs. drive current, which illustrates an example technique for achieving single longitudinal mode operation of a wavelength-stabilized laser diode. FIG. 3 illustrates the output optical power of the laser diode as a function of operating current (at a specific temperature) for a laser that is capable of SLM operation. The plot shown in FIG. 3 includes photodiode monitor current vs. operating current over a range of operating currents from 140 mA to 180 mA. It should be understood that the monitor current is proportional to the output optical power of the laser. This method allows achieving SLM operation without a high-resolution wavelength discriminator, but rather with a simple power monitor.

Sudden jumps in output power correspond to changes in the operating condition of the laser. That is, the sudden jumps in output power indicate when the laser switches between SLM and non-SLM operation, and also between different longitudinal modes within the SLM regime. Using the features of the output power vs operating current it is possible to identify regions of SLM operation, as noted in FIG. 3, without actually monitoring laser wavelength.

The system may be configured such that, on startup, the system executes a search algorithm to perform a scan of monitor current vs drive current to determine what drive current regions produce SLM operation. Depending on the desired output power, a corresponding drive current may be determined from the monitor current that corresponds to the desired output power. For example, if the desired output power corresponds to a monitor current of 120 μA, then SLM operation of the laser diode may be achieved at a drive current of 142 mA. The laser is tuned to an SLM condition by monitoring its output power and adjusting the drive current and operating temperature.

Note that SLM operation may not be achievable for all output powers at any given temperature. For example, as shown in FIG. 3, there is no drive current that will produce SLM operation of the laser at an output power that corresponds to a monitor current of 132 μA. But, the output power vs drive current plot will shift as a function of temperature. Accordingly, the temperature of the laser diode may be adjusted until SLM operation is achievable at the desired output power.

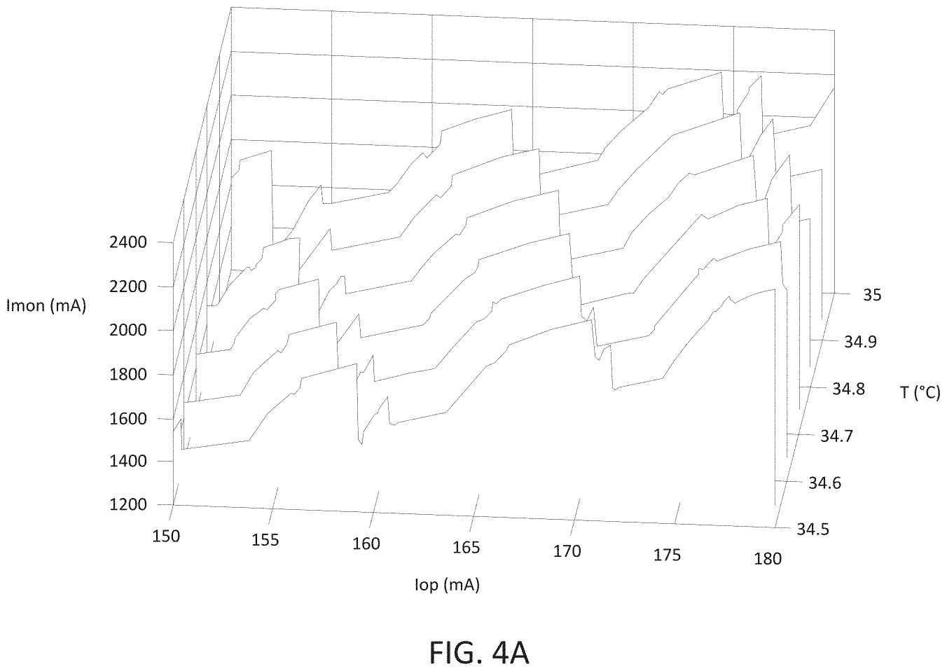

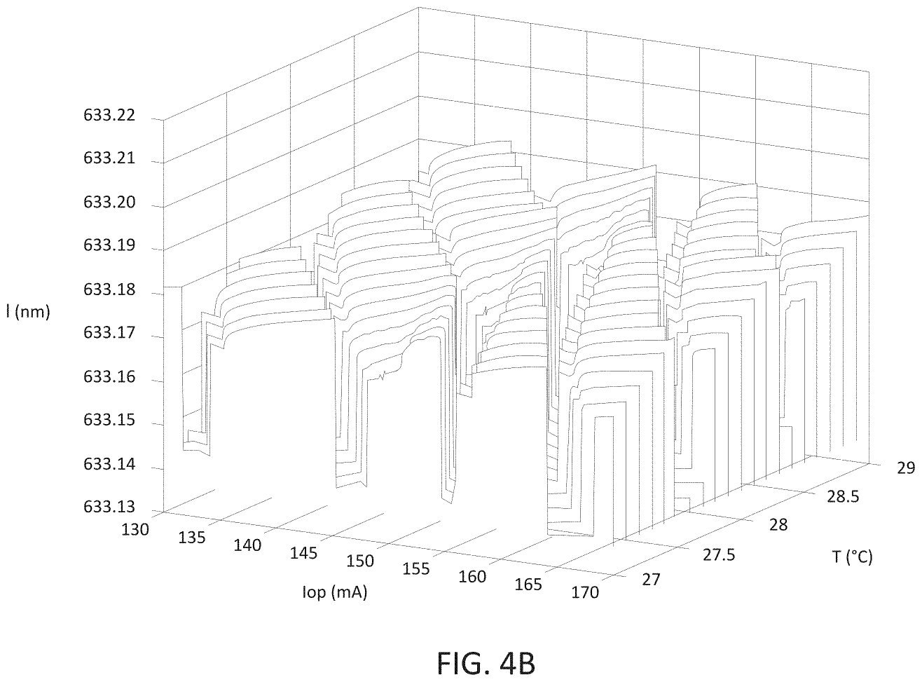

FIG. 4A is three-dimensional plot of output optical power as a function of drive current and temperature. FIG. 4B is three-dimensional plot of wavelength as a function of drive current and temperature. It should be understood from these plots that temperature and drive current may be adjusted to achieve a desired optical power, to thereby eliminate mode hops as the output optical power is tuned. Thus, FIGS. 4A and 4B illustrate an example technique for eliminating mode hops during wavelength tuning of an SLM laser diode system.

FIG. 5 provides a functional block diagram of an example laser controller 528. As shown, the laser controller 528 may include one or more controllers, each of which is adapted to control a respective characteristic of the laser diode 510. For example, the laser controller 528 may include a cavity length controller, a temperature controller, and a drive current controller.

The laser controller 528 may be instructed by commands received from the processor 526. In response to the commands received from the processor 526, the laser controller 528 may instruct one or more of the characteristic controller(s) 529 to alter a respective characteristic of the laser diode 510.

For example, the cavity length controller may instruct a cavity length adjuster to adjust the cavity length of the laser diode 510. The cavity length controller may cause the cavity length to be adjusted by causing the cavity length adjuster to increase or decrease the distance between the gain medium and the feedback grating element. The cavity length adjuster may be an electromechanical element, such as a piezo element, for example.

The temperature controller may instruct a heating/cooling element to adjust the temperature of the laser diode 510. The temperature controller may cause the temperature of the laser diode 510 to be adjusted by causing the heating/cooling element to draw more or less thermal energy from the laser diode 510. The heating/cooling element may be a thermoelectric cooler, for example.

The drive current controller may instruct a current driver to adjust the drive current of the laser diode 510. The drive current controller may cause the drive current of the laser diode 510 to be adjusted by causing the current driver to provide more or less drive current to the laser diode 510.

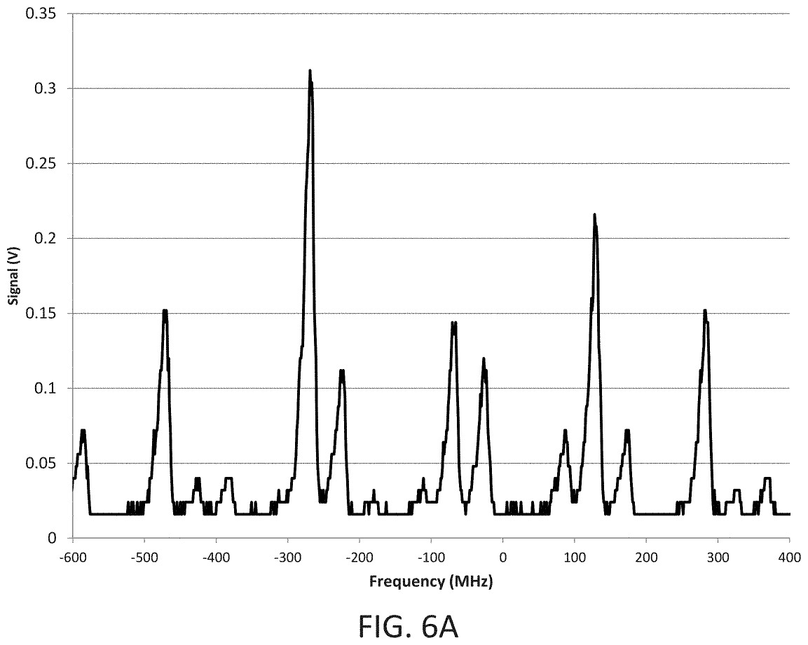

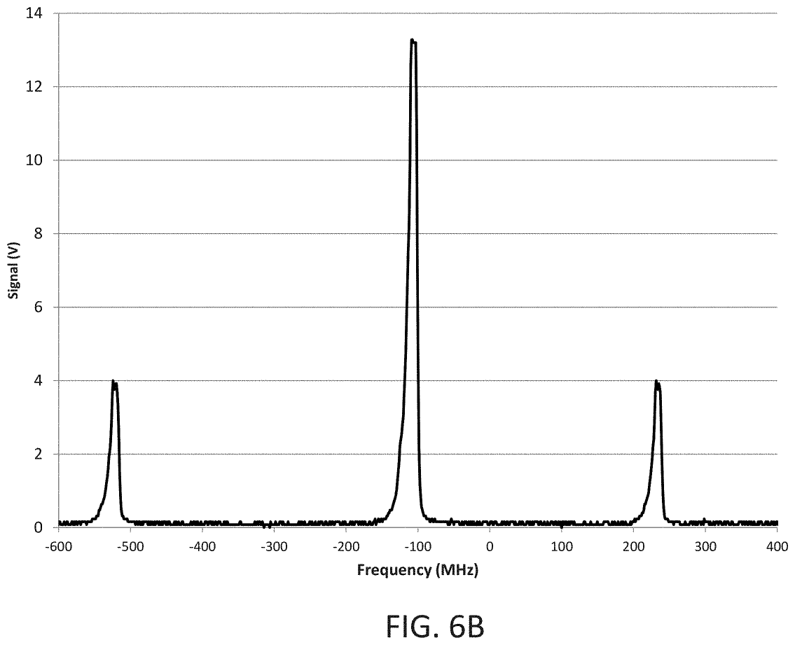

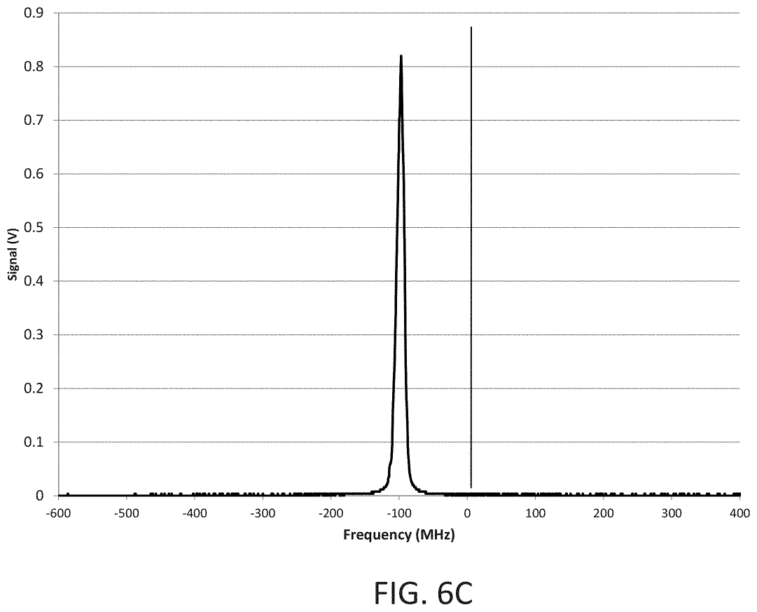

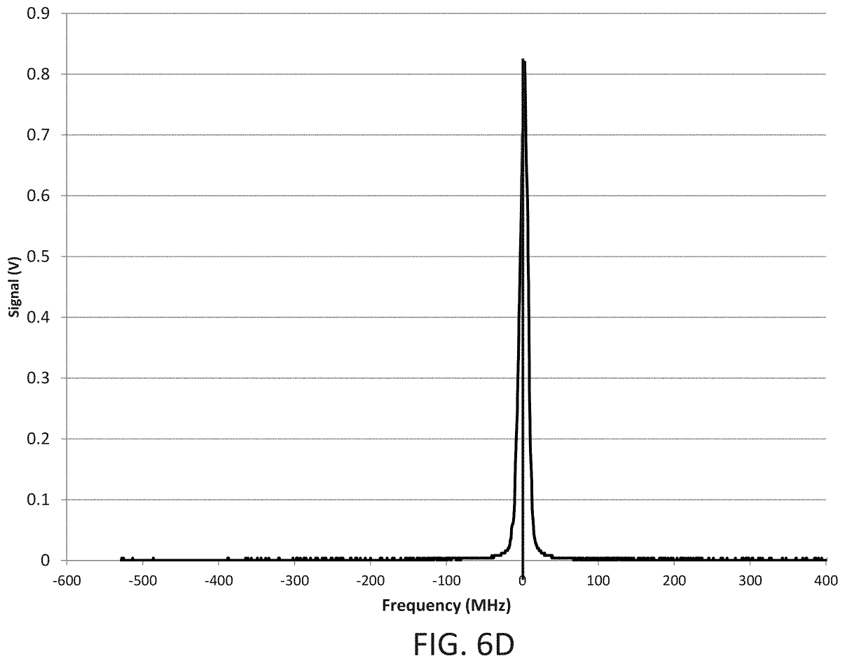

FIG. 6A illustrates the output spectrum (i.e., power vs. wavelength) from a non-stabilized laser diode. As shown in FIG. 6A, a non-stabilized laser diode produces a broadband, spectrally uncontrolled, output.

FIG. 6B illustrates the output spectrum from a wavelength-stabilized multi-longitudinal mode laser diode. As shown in FIG. 6B, a stabilized multi-longitudinal mode laser diode produces several longitudinal modes, albeit much more spectrally controlled.

FIG. 6C illustrates the output spectrum from a stabilized SLM laser diode without active wavelength control (that is, without an active feedback loop as described herein). As shown in FIG. 6C, a stabilized SLM laser diode without active wavelength control produces a single longitudinal mode having a wavelength that is relatively near the desired operating wavelength of the laser diode (which is shown by the vertical line at 0 in FIG. 6C).

FIG. 6D illustrates the output spectrum from a stabilized SLM laser diode with active wavelength control. As shown in FIG. 6D, with active wavelength control, the laser diode system may produce a single longitudinal mode having a wavelength that is within a very small window centered on the desired operating wavelength of the laser diode (which is shown by the vertical line at 0 in FIG. 6D). By employing both laser stabilization and active wavelength control as described herein, a laser diode may be operated with the wavelength stability and precision that is desirable for applications that have historically required gas lasers.

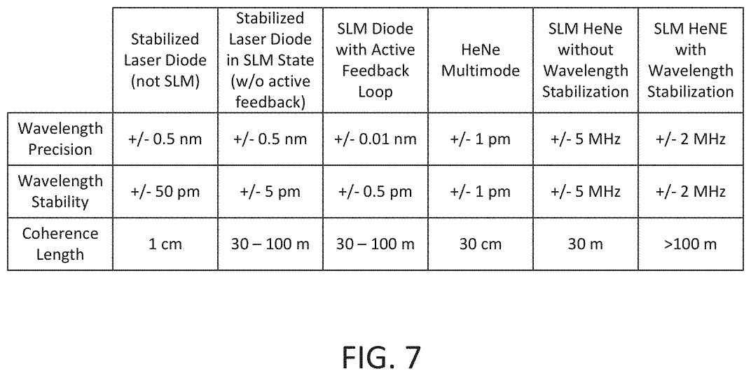

FIG. 7 provides a table that compares wavelength precision, wavelength stability, and coherence length data for several different laser types. As shown, a typical stabilized laser diode that is not operating in single longitudinal mode may have a wavelength precision of about +/−0.5 nanometers, a wavelength stability of +/−50 picometers, and a coherence length of about 1 centimeter. A typical stabilized laser diode that is operating in single longitudinal mode without active feedback may have a wavelength precision of about +/−0.5 nanometers, a wavelength stability of +/−5 picometers, and a coherence length of about 30-100 meters. A typical SLM diode with an active feedback loop may have a wavelength precision of about +/−0.01 nanometers, a wavelength stability of +/−0.5 picometers, and a coherence length of about 30-100 meters.

A typical HeNe multimode laser diode may have a wavelength precision of about +/−1 picometer, a wavelength stability of +/−1 picometer, and a coherence length of about 30 centimeters. A typical SLM HeNe laser diode without wavelength stabilization may have a wavelength precision of about +/−5 MHz, a wavelength stability of +/−5 MHz, and a coherence length of about 30 meters. A typical SLM HeNe laser diode with wavelength stabilization may have a wavelength precision of about +/−2 MHz, a wavelength stability of +/−2 MHz, and a coherence length of more than about 100 meters.

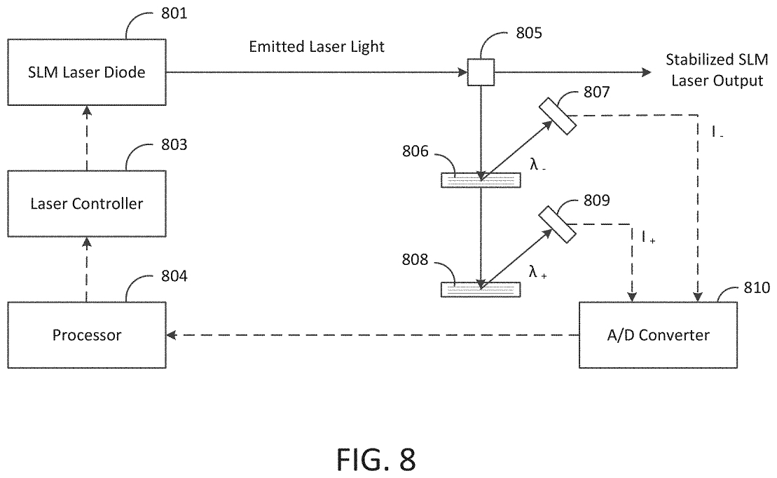

FIG. 8 provides a detailed functional block diagram of an example wavelength discriminator. As shown, light from an SLM laser diode 801 is incident on a beam sampler 805. The beam sampler 805 directs a portion of the incident light toward a first wavelength selective element 806. The beam sampler 805 may be a VBG element, for example, or a non-wavelength-selective element. The wavelength selective element 806 may be, for example, a VBG element or a diffractive grating. The wavelength selective element 806 directs light having a wavelength, λ₋, toward a photodetector 807. The photodetector 807 produces a current, I₋, that is proportional to the energy received at the photodetector 807.

The wavelength selective element 806 directs at least a portion of the incident light toward a second wavelength selective element 808. The wavelength selective element 808 may be, for example, a VBG element or a diffractive grating. The wavelength selective element 808 directs light having a second wavelength, λ₊, toward a second photodetector 809. The photodetector 809 produces a current, I₊, that is proportional to the energy received at the photodetector 809. The wavelengths, λ₊ and λ₋, respectively, may be chosen to be plus and minus a small offset to the desired operating wavelength, λ₀.

The currents I₊ and I₋ are fed into an analog-to-digital converter 810. The digitized current streams are provided to the processor 804. The processor 804 determines from the digitized current streams whether the laser diode 801 is emitting at the desired operating wavelength, λ₀. For example, the processor 804 may determine that the laser diode is operating at the desired operating wavelength, λ₀, if the currents I₊ and I₋ are balanced. If the processor determines that the currents I₊ and I₋ are not balanced, and therefore that the laser diode is not emitting at the desired operating wavelength, λ₀, then the processor may instruct the laser controller 803 to adjust one or more characteristics of the laser diode in a manner that would be expected to move the actual operating wavelength closer to the desired operating wavelength, λ₀.

Basically, it should be understood that the wavelength discriminator will have a certain bandwidth. The bandwidth of the wavelength discriminator may correspond to a desired stabilization range, that is, the range of wavelength in which the wavelength stabilization system is able to control the operating wavelength of the laser diode. The laser diode can be stabilized more precisely when it can detect in this range.

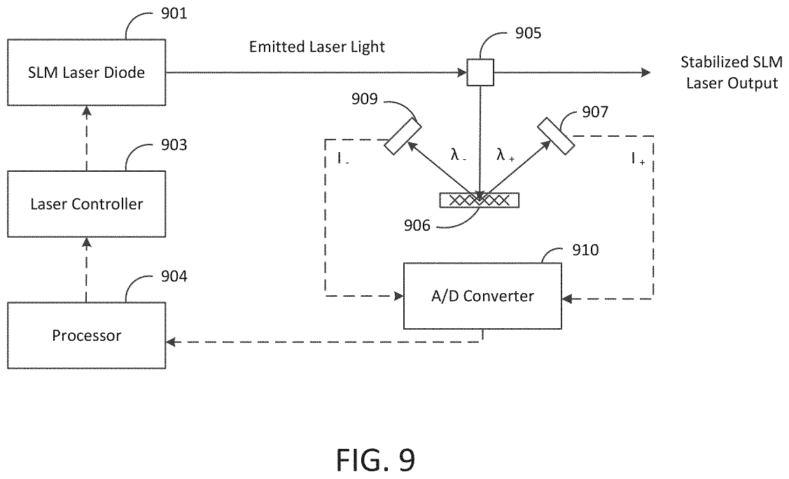

FIG. 9 provides a detailed functional block diagram of another example wavelength discriminator. As shown, light from an SLM laser diode 901 is incident on a beam sampler 905. The beam sampler 905 directs a portion of the incident light toward a wavelength selective element 906. The beam sampler 905 may be a VBG element, for example, or a non-wavelength-selective element. The wavelength selective element 906 may be, for example, a VBG element or a diffractive grating. The wavelength selective element 906 directs a portion of the light, having a wavelength, λ₊, toward a photodetector 907. The photodetector 907 produces a current, I₊, that is proportional to the energy received at the photodetector 907.

The wavelength selective element 906 directs a portion of the light having a wavelength, λ₋, toward a second photodetector 909. The photodetector 909 produces a current, I₋, that is proportional to the energy received at the photodetector 809. The wavelengths, λ₊ and λ₋, respectively, may be chosen to be plus and minus a small offset to the desired operating wavelength, λ₀.

The currents I₊ and I₋ are fed into an analog-to-digital converter 910. The digitized current streams are provided to the processor 904. The processor determines from the digitized current streams whether the laser diode is emitting at the desired operating wavelength, λ₀. If the processor determines that the laser diode is not emitting at the desired operating wavelength, λ₀, then the processor instructs the laser controller 903 to adjust one or more characteristics of the laser diode in a manner that would be expected to move the actual operating wavelength closer to the desired operating wavelength, λ₀.

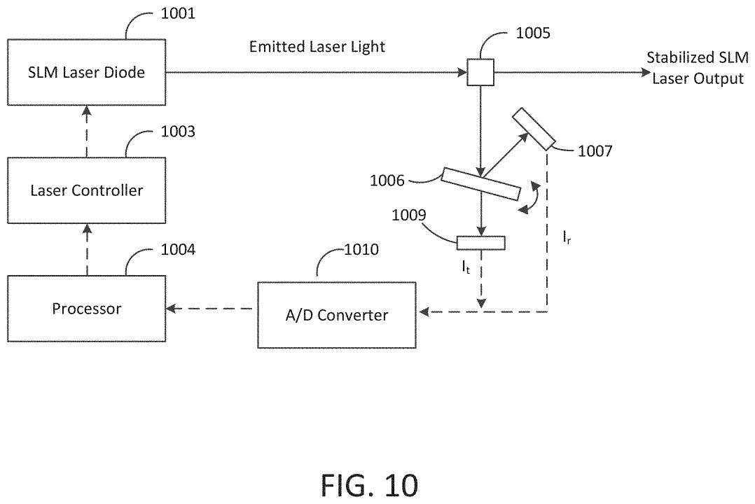

FIG. 10 provides a detailed functional block diagram of an example wavelength discriminator using an etalon. As shown, light from an SLM laser diode 1001 is incident on a beam sampler 1005. The beam sampler 1005 directs a portion of the incident light toward an etalon 1006. The beam sampler 1005 may be a VBG element, for example, or a non-wavelength-selective element. The etalon 1006 reflects a portion of the light, having a wavelength, λᵣ, toward a photodetector 1012. The photodetector 1012 produces a current, Iᵣ, that is proportional to the energy received at the photodetector 1012.

The etalon 1006 transmits a portion of the light having a wavelength, λ₋, toward a second photodetector 1009. The photodetector 1009 produces a current, Iₜ, that is proportional to the energy received at the photodetector 1009. The wavelengths, λᵣ and λₜ, respectively, may be chosen to be plus and minus a small offset to the desired operating wavelength, λ₀, The etalon may be rotated to tune to the desired reflected and transmitted wavelengths, λᵣ and λₜ.

The currents I₊ and I₋ are fed into an analog-to-digital converter 1010. The digitized current streams are provided to the processor 1004. The processor 1004 determines from the digitized current streams whether the laser diode 1001 is emitting at the desired operating wavelength, λ₀. If the processor 1004 determines that the laser diode 1001 is not emitting at the desired operating wavelength, λ₀, then the processor 1004 instructs the laser controller 1003 to adjust one or more characteristics of the laser diode 1001 in a manner that would be expected to move the actual operating wavelength closer to the desired operating wavelength, λ₀.

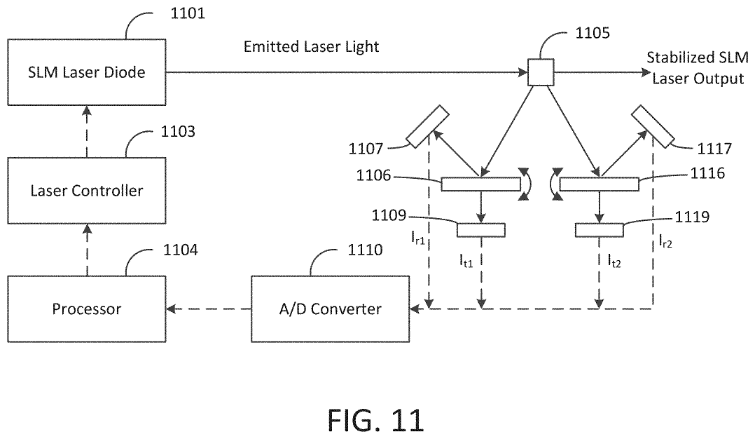

FIG. 11 provides a detailed functional block diagram of another example wavelength discriminator using etalons. As shown, light from an SLM laser diode 1101 is incident on a beam sampler 1105. The beam sampler 1105 directs a portion of the incident light toward an etalon 1106. The beam sampler 1105 may be a VBG element, for example, or a non-wavelength-selective element. The etalon 1106 reflects a portion of the light, having a wavelength, λᵣ₁, toward a photodetector 1107. The photodetector 1107 produces a current, Iᵣ₁, that is proportional to the energy received at the photodetector 1107.

The etalon 1106 transmits a portion of the light having a wavelength, λₜ₁, toward a second photodetector 1109. The photodetector 1109 produces a current, Iₜ₁, that is proportional to the energy received at the photodetector 1109. The wavelengths, λᵣ₁ and λₜ₁, respectively, may be chosen to be plus and minus a small offset to the desired operating wavelength, λ₀. The etalon 1106 may be rotated to tune to the desired reflected and transmitted wavelengths, λᵣ₁ and λₜ₁.

The beam sampler 1105 directs a portion of the incident light toward a second etalon 1116. The etalon 1116 reflects a portion of the light, having a first wavelength, λᵣ₂, toward a photodetector 1117. The photodetector 1117 produces a current, Iᵣ₂, that is proportional to the energy received at the photodetector 1117.

The etalon 1116 transmits a portion of the light having a wavelength, λₜ₂, toward a photodetector 1119. The photodetector 1119 produces a current, Iₜ₂, that is proportional to the energy received at the photodetector 1119. The wavelengths, λᵣ₂ and λₜ₂, respectively, may be chosen to be plus and minus a small offset to the desired operating wavelength, λ₀. The etalon 1116 may be rotated to tune to the desired reflected and transmitted wavelengths, λᵣ₂ and λₜ₂.

The currents Iₜ₁, Iₜ₂, Iᵣ₁, and Iᵣ₂ are fed into an analog-to-digital converter 1110. The digitized current streams are provided to the processor 1104. The processor 1104 determines from the digitized current streams whether the laser diode 1101 is emitting at the desired operating wavelength, λ₀. If the processor 1104 determines that the laser diode 1101 is not emitting at the desired operating wavelength, λ₀, then the processor 1104 instructs the laser controller 1103 to adjust one or more characteristics of the laser diode 1101 in a manner that would be expected to move the actual operating wavelength closer to the desired operating wavelength, λ₀.

1. A semiconductor laser diode system, comprising:
a laser diode comprising a gain medium and an optical feedback device, wherein the optical feedback device is a three-dimensional optical element having a Bragg grating recorded therein, and wherein the Bragg grating causes a narrowband portion of radiation emitted from the gain medium to be fed back into the gain medium; and
a control system comprising an optical detector that receives light emitted from the laser diode without an intervening wavelength discriminator and produces a monitor current that is proportional to an output optical power of the laser diode,
wherein the control system monitors the monitor current and, based on sudden increases in the monitor current, the control system adjusts at least one of a laser drive current or a laser operating temperature to cause the laser diode to achieve and maintain a single longitudinal mode operating condition.

2. The semiconductor laser diode system of claim 1, wherein the narrowband portion of the radiation emitted from the gain medium that is fed back into the gain medium is seed light at a desired wavelength.

3. The semiconductor laser diode system of claim 2, wherein the Bragg grating causes the seed light to be reflected back into the gain medium.

4. The semiconductor laser diode system of claim 1, wherein the control system comprises an optical detector and a microprocessor, wherein the optical detector detects an optical power output from the laser diode, and wherein the microprocessor receives an electrical signal representative of the output optical power from the optical detector.

5. The semiconductor laser diode system of claim 4, wherein the microprocessor is configured to analyze the electrical signal and to command a laser controller to adjust a laser drive current to cause the laser diode to achieve and maintain the single longitudinal mode operating condition.

6. The semiconductor laser diode system of claim 4, wherein the microprocessor is configured to analyze the electrical signal and to command a laser controller to adjust a laser operating temperature to cause the laser diode to achieve and maintain the single longitudinal mode operating condition.

7. The semiconductor laser diode system of claim 1, wherein the control system monitors the monitor current as a function of the laser drive current.

8. The semiconductor laser diode system of claim 1, wherein the control system monitors the monitor current as a function of the laser operating temperature.

9. A semiconductor laser diode system, comprising:
a semiconductor laser diode comprising a laser source and having a laser cavity;
an optical feedback device that causes a narrowband portion of radiation emitted from the laser source to be fed back into the laser cavity; and
a control system comprising an optical detector that receives light emitted from the laser diode without an intervening wavelength discriminator and produces a monitor current that is proportional to an output optical power of the laser diode,
wherein the control system monitors the monitor current and, based on sudden increases in the monitor current, the control system causes the laser diode to achieve and maintain a single longitudinal mode operating condition, and
wherein the laser diode system produces laser light having a coherence length of at least 30 meters, a wavelength precision of +/−0.01 nm, and a wavelength stability of +/−0.5 picometers.

10. The semiconductor laser diode system of claim 9, further comprising a temperature controller that is configured to cause a temperature of the laser diode to be adjusted.

11. The semiconductor laser diode system of claim 9, further comprising a drive current controller that is configured to cause a drive current of the laser diode to be adjusted.

12. The semiconductor laser diode system of claim 9, further comprising a cavity length controller that is configured to cause a cavity length of the laser diode to be adjusted.

13. The semiconductor laser diode system of claim 9, wherein the control system comprises an optical detector and a microprocessor, wherein the optical detector detects an optical power output from the laser diode, and wherein the microprocessor receives an electrical signal representative of the output optical power from the optical detector.

14. The semiconductor laser diode system of claim 13, wherein the microprocessor is configured to analyze the electrical signal and to command a laser controller to adjust a laser drive current to cause the laser diode to achieve and maintain the single longitudinal mode operating condition.

15. The semiconductor laser diode system of claim 13, wherein the microprocessor is configured to analyze the electrical signal and to command a laser controller to adjust a laser operating temperature to cause the laser diode to achieve and maintain the single longitudinal mode operating condition.

16. The semiconductor laser diode system of claim 9, wherein the control system monitors the monitor current as a function of the laser drive current.

17. The semiconductor laser diode system of claim 9, wherein the control system monitors the monitor current as a function of the laser operating temperature.
